(19) United States
(12) Patent Application Publication
(10) Pub. No.: US 2014/0095769 A1
(43) Pub. Date: Apr. 3, 2014

(54) FLASH MEMORY DUAL IN-LINE MEMORY MODULE MANAGEMENT

(71) Applicant: INTERNATIONAL BUSINESS MACHINES CORPORATION, Armonk, NY (US)

(72) Inventor: John M. Borkenhagen, Rochester, MN (US)

(73) Assignee: INTERNATIONAL BUSINESS MACHINES CORPORATION, Armonk, NY (US)

(21) Appl. No.: 13/633,655

(22) Filed: Oct. 2, 2012

(51) Int. Cl. G11C 16/06; G06F 12/00

(52) U.S. Cl. 711/103; 365/185.08; 711/E12.008

(57) ABSTRACT

Systems and methods to manage memory on a dual in-line memory module (DIMM) are provided. A particular method may include receiving at a flash application-specific integrated circuit (ASIC) a request from a processor to access data stored in a flash memory of a DIMM. The data may be transferred from the flash memory to a switch of the DIMM. The data may be routed to a dynamic random-access memory (DRAM) of the DIMM. The data may be stored in the DRAM and may be provided from the DRAM to the processor.

### I. FIELD OF THE DISCLOSURE

The present disclosure relates generally to computer memory architectures, and in particular, to a system and a method managing access to memory.

### II. BACKGROUND

Flash memory is widely used in data centers due for its ability to be electrically erased and reprogrammed. Flash memory is implemented in multiple form factors, such as solid state disk (SSD), as well as on Peripheral Component Interconnect Express (PCIe) flash cards. Efforts to incorporate flash memory into dual in-line memory module (DIMM) form factors have been complicated by the underlying NAND technology of flash memory. NAND memory is not cache coherent and too slow to be accessed by DIMM processors without incurring delays or requiring switching contexts. Using cache line memory reads and writes can consume processing cycles and memory bus bandwidth.

### III. SUMMARY OF THE DISCLOSURE

In another embodiment, an apparatus may include a flash memory, a dynamic random-access memory (DRAM), and a flash application-specific integrated circuit (ASIC). The flash ASIC may be in communication with the flash memory and the DRAM. The flash ASIC may further be configured to enable data to be transferred between the flash memory and the DRAM.

In a particular embodiment, a method of managing a memory may include receiving at a flash ASIC a request from a processor to access data stored in a flash memory of a dual in-line memory module (DIMM). The data may be transferred from the flash memory to a switch of the DIMM. The data may be routed to a DRAM of the DIMM. The data may be stored in the DRAM and may be provided from the DRAM to the processor.

Another particular embodiment may include a method of managing a memory that comprises including a flash memory within a DIMM. A DRAM may be included within the DIMM, as well as a flash ASIC. The flash ASIC may be configured to enable data to be transferred between the flash memory and the DRAM.

An embodiment may avoid expending processor cycles when copying data between the non-coherent flash memory and the coherent DRAM of a DIMM. The processor may thus accomplish other work during the copy operation. The increased work capacity may result in increased system performance. Data transfers may be accomplished without using CPU cycles or initiating traffic on the memory bus to which the DIMM is attached. A system may be able to continue accessing data from the other DIMMs on the memory bus during the copy operation. The data may alternatively remain internal to the DIMM. The internal data transfer may reduce power usage and increase efficiency.

An embodiment may be compatible with industry standard processors and memory controllers. No logic changes or additional support may be necessary in the processor or memory controller logic. The operating system and/or hypervisor may inhibit or prevent memory accesses to the flash DIMM during the copy procedure to avoid collisions on the use of the DRAM during a copy operation. Accesses to other DIMMs may continue, including DIMMs on the same memory bus as the flash DIMM.

Features and other benefits that characterize embodiments are set forth in the claims annexed hereto and forming a further part hereof. However, for a better understanding of the embodiments, and of the advantages and objectives attained through their use, reference should be made to the Drawings and to the accompanying descriptive matter.

### IV. BRIEF DESCRIPTION OF THE DRAWINGS

FIG. 1 is a block diagram of a computing system configured to manage memory access in a manner consistent with an embodiment;

FIG. 2 is a block diagram of the primary software components and resources of the computing system of FIG. 1;

FIG. 3 is a block diagram of a memory management having application in the computing system of FIG. 1;

FIG. 4 is a block diagram a dual in-line memory module of the memory management system of FIG. 3 having both flash memory and dual in-line memory module; and

FIG. 5 is a flowchart of an embodiment of a method of managing a hybrid dual in-line memory module having both flash memory and dynamic random-access memory resources using the computing system of FIGS. 1-4.

### V. DETAILED DESCRIPTION

A dual in-line memory module (DIMM) may be a hybrid of both flash and dynamic random-access memory (DRAM). The DRAM address range may be accessed as standard coherent memory. Flash memory data may be read as non-coherent memory and moved to the DRAM coherent address range to be used as coherent memory by the server. Flash memory DIMM implementations may include buffer chips on the memory bus interface to hide the increased loading of the flash memory. The transfer of data may not use cycles of a central processing unit (CPU) or add traffic to the memory bus to which the DIMM is attached. The cycles of the CPU may thus be available to do work other than copying data. A server or other computing system may be enabled to continue accessing data from the other DIMMs on the memory bus.

An embodiment may leverage features of a hybrid flash/DRAM DIMM architecture by adding a data path that is internal to the DIMM. For example, an illustrative data path may be added behind the buffer to the memory DIMM bus. The data path may support moving data back and forth between the flash memory and the DRAM.

A control register(s) and a read/write copy engine(s) may be included in the flash memory control application-specific integrated circuit (ASIC). The control register and the read/write copy engine may be used to transfer data from the flash to the DRAM on the DIMM. An operating system and/or a hypervisor may write the flash ASIC control register with a source address range to be copied from flash and a target address range to be written to the DRAM.

An operating system and/or a hypervisor may temporarily prevent application memory accesses to a particular flash DIMM, while accesses may continue to other DIMMs. The operating system and/or a hypervisor may write the flash ASIC control register to initiate a data copy by the flash ASIC. The flash ASIC may copy data from the flash source address range to the DRAM target address range, and the data copy operation may complete. The operating system and/hypervisor may enable application memory access to the flash DIMM after a (safe) period of time or after the flash DIMM signals completion (for example, by an interrupt).

When data is moved from the coherent DRAM to the non-coherent flash memory, the source is the DRAM and the target is the flash memory. Conversely, the DRAM is the target and the flash memory is the source when data is moved from the flash memory to the DRAM.

An embodiment may not use processor cycles to copy data between the non-coherent flash memory and the coherent DRAM. The processor may thus accomplish other work during the copy operation. The increased work capacity may result in increased system performance.

The memory bus may not be used to copy data between the non-coherent flash memory and the coherent DRAM. The processor may continue to perform accesses on memory bus during a copy operation. Data may be transferred between the flash memory and the DRAM may not occur on the memory bus that has high capacitance. The data may alternatively remain internal to the DIMM. The internal data transfer may reduce power usage and increase efficiency.

An embodiment may be compatible with industry standard processors and memory controllers. No logic changes or additional support may be used in the processor or memory controller logic. The operating system and/or hypervisor may inhibit or prevent memory accesses to the flash DIMM during the copy procedure to avoid collisions on the use of the DRAM during a copy operation. Accesses to other DIMMs may continue, including DIMMs on the same memory bus as the flash DIMM.

The flash DIMM may support regular memory accesses during the copy operation. Copies may be performed only when in a low power mode where accesses to memory are not allowed. For example, the memory controller may instruct the hybrid flash DIMM to transition into low power mode because no memory accesses are waiting. The hybrid flash DIMM may then safely do copies to the DRAM without colliding with memory accesses. When the memory controller causes the hybrid flash DIMM to transition out of low power state to do memory accesses, the flash copies may be suspended to the regular memory accesses so they do not collide with flash copies to the DRAM.

An embodiment of the memory controller may be aware of the flash DIMM. By making the memory controller aware of when the flash DIMM is doing a copy between flash and DRAM, the memory controller may cooperate with the flash DIMM to continue to do accesses to DRAM on the Flash DIMM in the middle of the copy process. For example, if the memory controller does not have any DRAM read/write accesses to do, the memory controller may write a status bit to the flash ASIC to enable a copy operation to proceed. If the memory controller has memory DRAM read/write accesses to do in the middle of a flash copy operation, the memory controller may set the status bit to disable the data transfer process until the memory DRAM read/write accesses are complete.

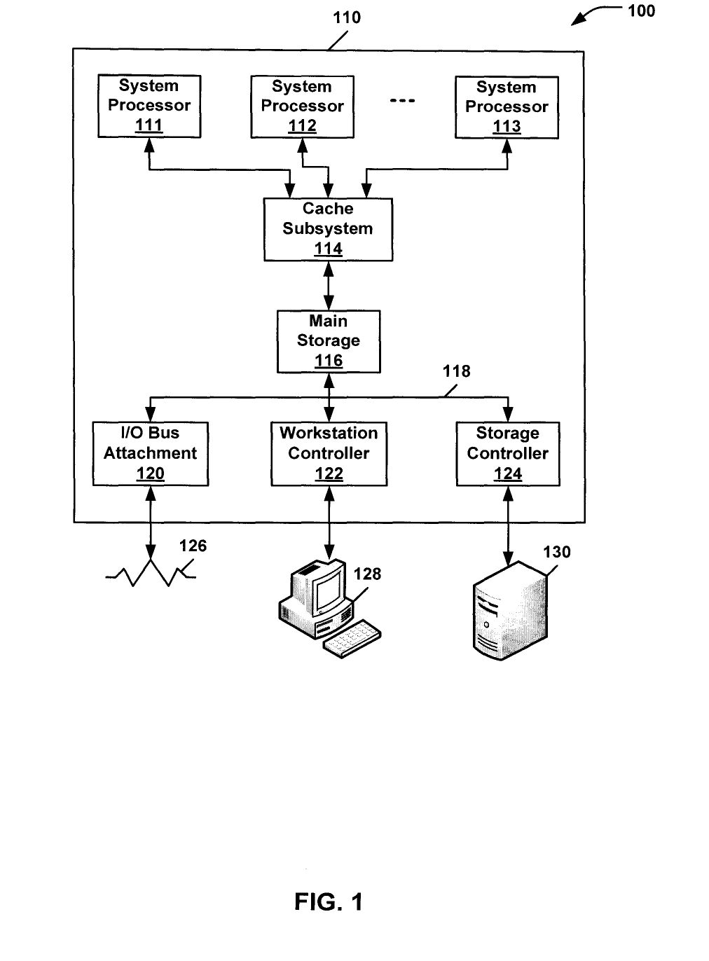

Turning more particularly to the drawings, FIG. 1 generally illustrates a data processing apparatus 100 consistent with an embodiment. The apparatus 100, in specific embodiments, may include a computer, a computer system, a computing device, a server, a disk array, client computing entity, or other programmable device, such as a multi-user computer, a single-user computer, a handheld device, a networked device (including a computer in a cluster configuration), a mobile phone, a video game console (or other gaming system), etc. The apparatus 100 may be referred to as a logically partitioned computing system or computing system, but may be referred to as computer for the sake of brevity. One suitable implementation of the computer 110 may be a multi-user computer, such as a computer available from International Business Machines Corporation (IBM).

The computer 110 generally includes one or more physical processors 111, 112, 113 coupled to a memory subsystem including a main storage 116. The main storage 116 may include one or more dual in-line memory modules (DIMMs). The DIMM may include an array of dynamic random-access memory (DRAM). Another or the same embodiment may a main storage having a static random access memory (SRAM), a flash memory, a hard disk drive, and/or another digital storage medium. The processors 111, 112, 113 may be multithreaded and/or may have multiple cores. A cache subsystem 114 is illustrated as interposed between the processors 111, 112, 113 and the main storage 116. The cache subsystem 114 typically includes one or more levels of data, instruction and/or combination caches, with certain caches either serving individual processors or multiple processors.

The main storage 116 may be coupled to a number of external input/output (I/O) devices via a system bus 118 and a plurality of interface devices, e.g., an I/O bus attachment interface 120, a workstation controller 122, and/or a storage controller 124 that respectively provide external access to one or more external networks 126, one or more workstations 128, and/or one or more storage devices such as a direct access storage device (DASD) 130. The system bus 118 may also be coupled to a user input (not shown) operable by a user of the computer 110 to enter data (i.e., the user input sources may include a mouse, a keyboard, etc.) and a display (not shown) operable to display data from the computer 110 (i.e., the display may be a CRT monitor, an LCD display panel, etc.). The computer 110 may also be configured as a member of a distributed computing environment and communicate with other members of that distributed computing environment through a network 126.

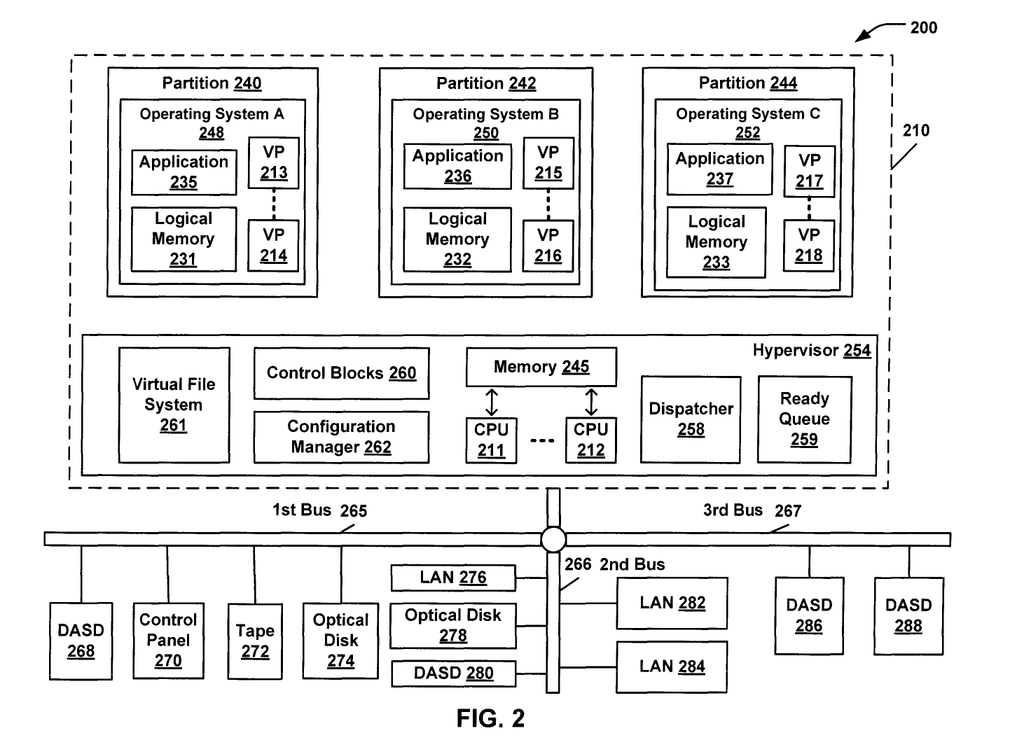

FIG. 2 illustrates in greater detail the primary software components and resources used to implement a logically partitioned environment consistent with a particular embodiment. FIG. 2 generally shows a logically partitioned computing system 200 having a computer 210 characterized as a virtual machine design, as developed by IBM. The computer 210 includes a plurality of partitions, e.g., partitions 240, 242 and 244, that share common processing resources. The logically partitioned computing system architecture may use a single computing machine having one or more processors 211, 212, or central processing units (CPU), coupled with a system memory 245. The system memory 245 may be incorporated into the cache subsystem 114, the main storage 116, or DASD 130 illustrated in FIG. 1, or into a separate memory. Referring back to FIG. 2, the processors 211, 212 may execute software configured to simulate one or more virtual processors (VPs) 213-218 in one or more logical partitions 240, 242, 244.

The logical partitions 240, 242, 244 may each include a portion of the processors 211, 212, the memory 245, and/or other resources of the computer 210. Each partition 240, 242, 244 typically hosts a respective operating environment, or operating system 248, 250, 252. After being configured with resources and the operating systems 248, 250, 252, each logical partition 240, 242, 244 generally operates as if it were a separate computer.

An underlying program, called a partition manager, a virtualization manager, or more commonly, a hypervisor 254, may be operable to assign and adjust resources to each partition 240, 242, 244. For instance, the hypervisor 254 may intercept requests for resources from the operating systems 248, 250, 252 or applications configured thereon in order to globally share and allocate the resources of computer 210. For example, when the partitions 240, 242, 244 within the computer 210 are sharing the processors 211, 212, the hypervisor 254 may allocate physical processor cycles between the virtual processors 213-218 of the partitions 240, 242, 244 sharing the processors 211, 212. The hypervisor 254 may also share other resources of the computer 210. Other resources of the computer 210 that may be shared include the memory 245, other components of the computer 210, other devices connected to the computer 210, and other devices in communication with computer 210. Although not shown, one having ordinary skill in the art will appreciate that the hypervisor 254 may include its own firmware and compatibility table. For purposes of this specification, a logical partition may use either or both the firmware of the partition 240, 242, 244, and hypervisor 254.

The hypervisor 254 may create, add, or adjust physical resources utilized by logical partitions 240, 242, 244 by adding or removing virtual resources from one or more of the logical partitions 240, 242, 244. For example, the hypervisor 254 controls the visibility of the physical processors 212 to each partition 240, 242, 244, aligning the visibility of the one or more virtual processors 213-218 to act as customized processors (i.e., the one or more virtual processors 213-218 may be configured with a different amount of resources than the physical processors 211, 212. Similarly, the hypervisor 254 may create, add, or adjust other virtual resources that align the visibility of other physical resources of computer 210.

Each operating system 248, 250, 252 controls the primary operations of its respective logical partition 240, 242, 244 in a manner similar to the operating system of a non-partitioned computer. For example, each logical partition 240, 242, 244 may be a member of the same, or a different, distributed computing environment. As illustrated in FIG. 2, the operating system 248, 250, 252 may include an application 235, 236, 237. In one embodiment, the application 235-237 is a middleware application that connects applications, processes, and/or software components. In the illustrated embodiment, the application 235-237 may consist of a set of enabling services that allow multiple processes running on one or more logical partitions of one or more computers to interact. As such, the application 235-237 may be a distributed application configured across multiple logical partitions (i.e., as shown in FIG. 2, across logical partitions 240, 242, 244) of one or more computers (i.e., as shown in FIG. 2, application is configured across computer 210) as part of a distributed computing environment. One such distributed computing environment is a WebSphere architecture, as developed by IBM, such that a business may set up, operate, and integrate network-based websites, applications, or businesses across one or more computing systems.

Each operating system 248, 250, 252 may execute in a separate memory space, represented by logical memories 231, 232, 233. For example and as discussed herein, each logical partition 240, 242, 244 may share the processors 211, 212 by sharing a percentage of processor resources as well as a portion of the available memory 245 for use in the logical memory 231-233. In this manner, the resources of a given processor 211, 212 may be utilized by more than one logical partition 240, 242, 244. In similar manners, the other resources available to computer 210 may be utilized by more than one logical partition 240, 242, 244.

The hypervisor 254 may include a dispatcher 258 that manages the dispatching of virtual resources to physical resources on a dispatch list, or a ready queue 259. The ready queue 259 comprises memory that includes a list of virtual resources having work that is waiting to be dispatched to a resource of computer 210. As shown in FIG. 2, the hypervisor 254 includes processors 211, 212 and processor control blocks 260. The processor control blocks 260 may interface with the ready queue 259 and comprise memory that includes a list of virtual processors 213-218 waiting for access on a respective processor 211, 212. Although FIG. 2 illustrates at least one processor control block 260 for each processor 211, 212, one skilled in the art will appreciate that the hypervisor 254 may be configured with more or less processor control blocks 260 than there are processors 211, 212.

The computer 210 may be configured with a virtual file system 261 to display a representation of the allocation of physical resources to the logical partitions 240, 242, 244. The virtual file system 261 may include a plurality of file entries associated with respective portion of physical resources of the computer 210 disposed in at least one directory associated with at least one logical partition 240, 242, 244. As such, the virtual file system 261 may display the file entries in the respective directories in a manner that corresponds to the allocation of resources to the logical partitions 240, 242, 244. Moreover, the virtual file system 261 may include at least one virtual file entry associated with a respective virtual resource of at least one logical partition 240, 242, 244.

Advantageously, a user may interface with the virtual file system 261 to adjust the allocation of resources to the logical partitions 240, 242, 244 of the computer 210 by adjusting the allocation of the file entries among the directories of the virtual file system 261. As such, the computer 210 may include a configuration manager (CM) 262, such as a hardware management console, in communication with the virtual file system 261 and responsive to the interaction with the virtual file system 261 to allocate the physical resources of the computer 210. The configuration manager 262 may translate file system operations performed on the virtual file system 261 into partition management commands operable to be executed by the hypervisor 254 to adjust the allocation of resources of the computer 210.

Additional resources, e.g., mass storage, backup storage, user input, network connections, and the like, are typically allocated to the logical partitions 240, 242, 244 in a manner well known in the art. Resources may be allocated in a number of manners, e.g., on a bus-by-bus basis, or on a resource-by-resource basis, with multiple logical partitions 240, 242, 244 sharing resources on the same bus. Some resources may also be allocated to multiple logical partitions at a time. FIG. 2 illustrates, for example, three logical buses 265, 266, 267. The bus 265 is illustrated with a plurality of resources, including a DASD 268, a control panel 270, a tape drive 272, and an optical disk drive 274. All the resources may be allocated on a shared basis among logical partitions 240, 242, 244. Bus 266, on the other hand, may have resources allocated on a resource-by-resource basis, e.g., with a local area network (LAN) adapter 276, an optical disk drive 278, and a DASD 280 allocated to the logical partition 240, and LAN adapters 282 and 284 allocated to the logical partition 242. The bus 267 may represent, for example, a bus allocated specifically to logical partition 244, such that all resources on the bus, e.g., DASDs 286, 288 are allocated to the same logical partition.

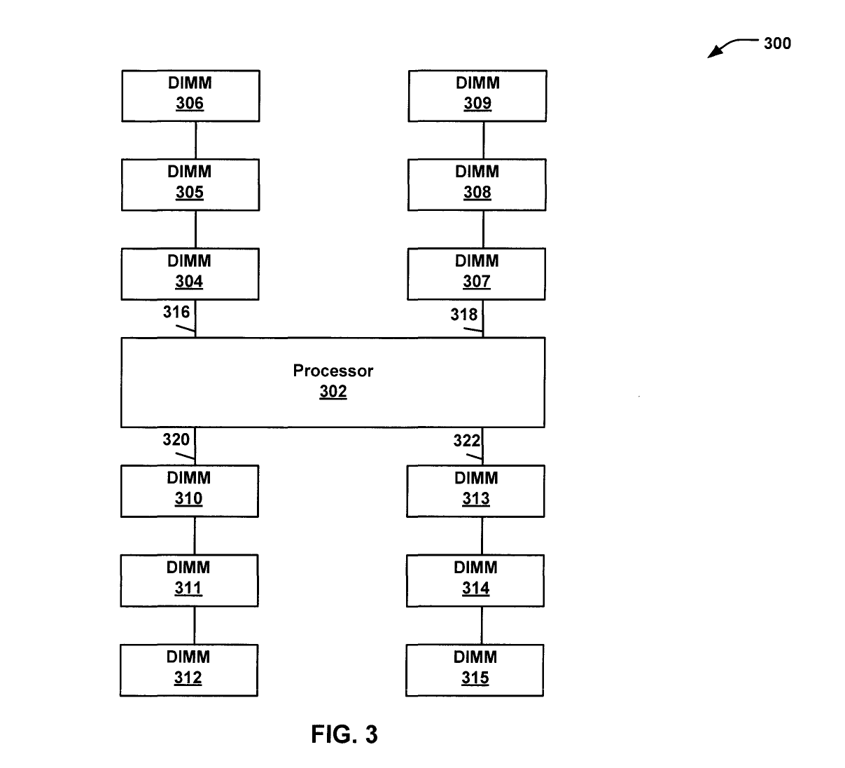

FIG. 3 shows an apparatus 300 that includes a processor 302 coupled to a plurality of DIMMs 304-313. At least one DIMM 304 may be a hybrid of both flash memory and DRAM. As discussed herein, processes executed by the one or more of the processor 302 and the DIMMs 304-313 may support the movement of data from non-coherent flash memory space to coherent DRAM memory space on a hybrid flash/DRAM DIMM 304. The data transfer may be accomplished without using processor cycles or traffic on the memory bus 316 to which the DIMM 304 is attached. The cycles of the processor 302 may thus be available to do work other than copying data. The processor 302 may be enabled to continue accessing data from the other DIMMs 305, 306 on the memory bus 316.

The DIMMs 304-313 may correspond to the main storage 116 of FIG. 1, and the processor 302 may correspond to a system processor 111. The DIMMs 304-306 may be coupled to the processor 302 via the memory bus 316. The DIMMs 307-309 may be coupled to the processor 302 via the memory bus 318, and the DIMMs 310-312 may be coupled to the processor 302 via the memory bus 320. The DIMMs 313-315 may be coupled to the processor 302 via the memory bus 322.

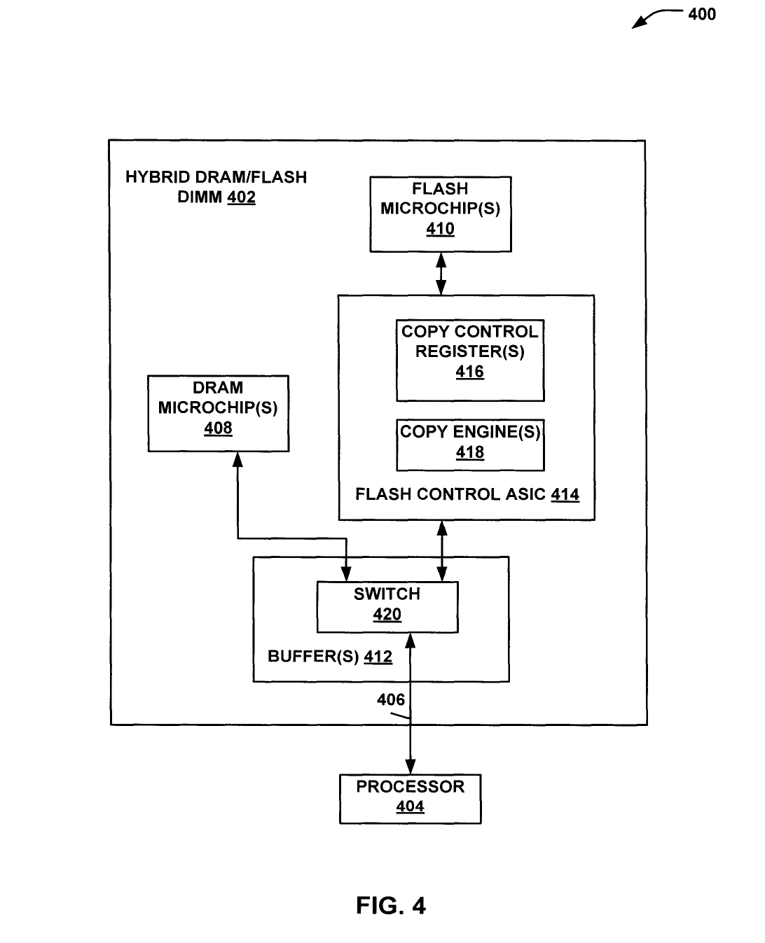

FIG. 4 is a block diagram of an apparatus 400 that includes a DIMM 402 and a processor 404. The DIMM 402 may be a hybrid of both flash and of DRAM. The DIMM 402 may correspond to the DIMM 304 of FIG. 3, and the processor 404 may correspond to the processor 302. A memory bus 406 may correspond to the memory bus 316 of FIG. 3.

Instead of moving NAND/flash memory data across the memory bus 406, NAND memory data may be moved internally with respect to the DIMM 402 via a switch 420 or other connection. More particularly, data may be moved internally from the flash microchip 410 to the DRAM microchips 408. The transferred NAND data may then be read at DRAM speed. By hiding from the processor 404 the memory transfer operation, processing cycles otherwise expended on the memory bus 406 may be spared. The other portions of the DIMM 402 (e.g., the DRAM microchips 408) may be accessed directly by the processor 404 via the memory bus 316 with normal (e.g., non-flash memory) operation.

The DIMM 402 may include one or more DRAM microchips 408 and one or more flash microchips 410 coupled to one or more buffers 412. A buffer 412 may be configured to temporarily hold data transferred between the DRAM microchips 408, the flash control ASIC 414, and the memory bus 406. The buffer 412 may include a switch 420 configured to control access from the processor 404 (and the memory bus 406) to the DRAM microchips 408 and a flash control application-specific integrated circuit (ASIC) 414. The processor 404 may be configured to write to the DRAM microchips 408 and the flash control ASIC 414 via the switch 420, as determined by the read or write address. During a data transfer operation, the flash control ASIC 414 may manage operation of the switch 420 to move data between the DRAM microchips 408 and the flash microchips 410. The flash control ASIC 414 may prohibit access to the DIMM 402 while the data is being transferred.

The flash microchip 410 may be coupled to the buffer 412 via the flash control ASIC 414. The flash control ASIC 414 may include one or more copy control registers 416 and one or more copy engines 418. A copy control register 416 may include address ranges (i.e., source and/or target addresses) to be used during the copy operation. An embodiment of the copy control register 416 may include memory mapped input/output (I/O) addresses associated with the flash microchip 410. A copy engine 418 may be used by the hypervisor, along with the copy control registers 416, to control or otherwise facilitate flash and DRAM copy operations.

One or more of the DRAM microchips 408 may include a main memory region and a memory mapped input/output I/O region. On a read operation to the DRAM microchips 408, a requested address may be predefined in the main memory region. The memory mapped I/O region of an embodiment may map address commands into and out of the DIMM 402 using addresses corresponding to both the DRAM microchips 408 and the flash microchips 410.

The DRAM microchips 408 may have different power states for energy conservation considerations. The DRAM microchips 408 may require time to transition from a standby or other low power state back to an active state. According to a particular embodiment, a copy operation may be accomplished before the DRAM microchip 408 is transitioned into a lower power state. For instance, an outstanding copy operation may be initiated in response to the DIMM 402 receiving a signal that a DRAM microchip 408 will be entering a standby power mode. As such, an embodiment of an apparatus may include communications and other cooperation between at least two of the processor 404, the hypervisor, the DRAM microchips 408, and the flash control ASIC 414 regarding DRAM power states.

FIG. 4 thus shows a block diagram of a computing system 400 configured to manage a hybrid DIMM 402 having both flash microchips 410 and DRAM microchips 408. An embodiment may avoid expending processor cycles when copying data between the non-coherent flash microchips 410 and the coherent DRAM microchips 408. The processor may thus accomplish other work during the copy operation. The increased work capacity may result in increased system performance. Data transfers may be accomplished without using processor cycles or initiating traffic on the memory bus to which the DIMM is attached. The computing system 400 may be able to continue accessing data from the other DIMMs on the memory bus 406 during the copy operation. The internal data transfer may reduce power usage and increase efficiency.

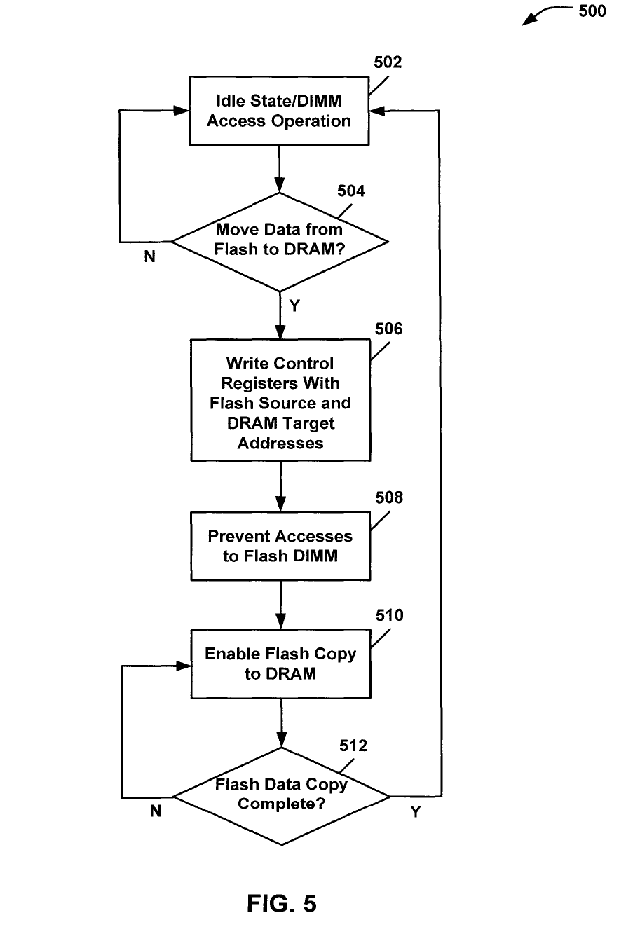

FIG. 5 is a flowchart of an embodiment of a method 500 of managing a hybrid DIMM having both flash memory and DRAM resources, such as in the computing environment of FIG. 4. More particularly, the method 500 may support the movement of data from the non-coherent flash memory space on a flash memory DIMM to coherent DRAM memory space on a hybrid flash/DRAM DIMM. In this manner, data moved from the flash memory to the DRAM may be accessed as coherent memory.

Turning more particularly to the flowchart, the flash memory DIMM may operate in an idle state at 502. While operating in the idle state, a hypervisor or operating system may enable normal DIMM memory access. For instance, memory accesses to the DRAM microchips 408 of the DIMM 402 of FIG. 4 may be allowed.

At 504, the hypervisor or operating system may determine that data should be transferred from non-volatile flash memory to DRAM. In one scenario, an application or a thread may need to access a location that is not in the DRAM. A page fault may be handled by the hypervisor or operating system, which determines the location from where to retrieve the requested data. For example, instead of going out to disc drive, the hypervisor may determine that requested data is located flash memory of the DIMM. The data may be moved from the flash memory into the DRAM with the assistance of the flash control ASIC. With reference to the FIGS. 2 and 4, the hypervisor 254 may determine that data should be moved from the flash microchip 410 to the DRAM microchip 408.

The hypervisor or operating system may at 506 write control registers with a flash memory source address and a DRAM target address. For instance, the control register 416 of FIG. 4 may be written with a flash memory source address that corresponds to the flash microchip 410. Another or the same control register 416 of FIG. 4 may be written with a DRAM target address that corresponds to the DRAM microchip 408. Data may be moved in and/or out of the DRAM microchip 408. For example, data may be moved out of the DRAM microchip 408 in order to make room for data transferred from the flash microchip 410. The copy operation may be coordinated with respect to a power stage of the DRAM.

At 508, the hypervisor or operating system may prevent memory access to the flash DIMM. For example, the hypervisor may prevent memory accesses to the DIMM 402 of FIG. 4 when an internal flash copy operation is ongoing, unless the flash control ASIC coordinates the memory access. Another exception may include copies that may be allowed during low power states. In either case, memory accesses by the processor may continue to other DIMMs on the memory bus that are not conducting a flash memory data transfer operation.

The flash memory copy to DRAM may be enabled at 510. The hypervisor or operating system may at 510 write the flash ASIC control register to provide the source and target addresses to enable the flash copy to DRAM. The flash ASIC control register may then conduct the flash memory copy operation.

The hypervisor or operating system may determine at 512 whether the flash data copy operation is complete. For instance, the hypervisor may determine that the data has been copied from the flash memory microchip 410 of FIG. 4 to the DRAM microchip 408. The determination may include checking a status register on the DRAM microchip. In another embodiment, the DIMM may interrupt the processor when the data transfer operation is complete. A determination of another embodiment may include a time-out command corresponding to how long a copy/transfer operation is expected to take to complete.

Where the copy operation is determined to be incomplete at 512, the hypervisor may continue to transfer data at 510. Alternatively, operation may return to the idle state at 502 when the operation is complete at 512.

Particular embodiments described herein may take the form of an entirely hardware embodiment, an entirely software embodiment or an embodiment containing both hardware and software elements. In a particular embodiment, the disclosed methods are implemented in software that is embedded in processor readable storage medium and executed by a processor, which includes but is not limited to firmware, resident software, microcode, etc.

Further, embodiments of the present disclosure, such as the one or more embodiments may take the form of a computer program product accessible from a computer-usable or computer-readable storage medium providing program code for use by or in connection with a computer or any instruction execution system. For the purposes of this description, a non-transitory computer-usable or computer-readable storage medium may be any apparatus that may tangibly embody a computer program and that may contain, store, communicate, propagate, or transport the program for use by or in connection with the instruction execution system, apparatus, or device.

In various embodiments, the medium may include an electronic, magnetic, optical, electromagnetic, infrared, or semiconductor system (or apparatus or device) or a propagation medium. Examples of a computer-readable storage medium include a semiconductor or solid state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and digital versatile disk (DVD).

A data processing system suitable for storing and/or executing program code may include at least one processor coupled directly or indirectly to memory elements through a system bus. The memory elements may include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) may be coupled to the data processing system either directly or through intervening I/O controllers. Network adapters may also be coupled to the data processing system to enable the data processing system to become coupled to other data processing systems or remote printers or storage devices through intervening private or public networks. Modems, cable modems, and Ethernet cards are just a few of the currently available types of network adapters.

The previous description of the disclosed embodiments is provided to enable any person skilled in the art to make or use the disclosed embodiments. Various modifications to these embodiments will be readily apparent to those skilled in the art, and the generic principles defined herein may be applied to other embodiments without departing from the scope of the disclosure. Thus, the present disclosure is not intended to be limited to the embodiments shown herein but is to be accorded the widest scope possible consistent with the principles and features as defined by the following claims.

1. An apparatus comprising:
a flash memory;
a dynamic random-access memory (DRAM); and
a flash application-specific integrated circuit (ASIC) in communication with the flash memory and the DRAM, wherein the flash ASIC is configured to enable data to be transferred between the flash memory and the DRAM.

2. The apparatus of claim 1, further comprising a switch module coupled to the DRAM the flash ASIC, and to a memory bus in communication with a processor, wherein the data is transferred from the flash memory to the DRAM via the switch module.

3. The apparatus of claim 1, wherein the apparatus is a dual in-line memory module (DIMM).

4. The apparatus of claim 1, wherein the flash ASIC is configured to prohibit access to at least one of the flash memory and the DRAM during a data transfer between the flash memory and the DRAM.

5. The apparatus of claim 4, wherein the flash memory and the DRAM are included in a first DIMM coupled to a memory bus, and wherein access is allowed to a second DIMM attached to the memory bus.

6. The apparatus of claim 1, wherein the flash ASIC is configured to coordinate a timing of a data transfer between the flash memory and the DRAM with regard to a power level of the DRAM.

7. The apparatus of claim 1, further comprising a buffer configured to buffer the data.

8. The apparatus of claim 1, further comprising a memory bus in communication with a processor.

9. The apparatus of claim 1, wherein the flash ASIC includes at least one copy control register.

10. The apparatus of claim 9, wherein the at least one copy control register includes at least one of a flash memory address and a DRAM address.

11. The apparatus of claim 1, wherein the flash ASIC includes a copy engine.

12. A method of managing memory, the method comprising:
receiving at a flash application-specific integrated circuit (ASIC) a request from a processor to access data stored in a flash memory of a dual in-line memory module (DIMM);
transferring the data from the flash memory to a switch of the DIMM;
routing the data to a dynamic random-access memory (DRAM) of the DIMM;
storing the data in the DRAM; and
providing the data from the DRAM to the processor.

13. A method of managing memory, the method comprising:
including a flash memory within a dual in-line memory module (DIMM);
including a dynamic random-access memory (DRAM) within the DIMM; and
including a flash application-specific integrated circuit (ASIC) within the DIMM, wherein the flash ASIC in configured to enable data to be transferred between the flash memory and the DRAM.

14. The method of claim 13, further comprising prohibiting access to at least one of the flash memory and the DRAM during a data transfer between the flash memory and the DRAM.

15. The method of claim 14, further comprising enabling access on another DIMM on a bus coupled to the DIMM.

16. The method of claim 13, further comprising transferring the data from the flash memory to the DRAM.

17. The method of claim 13, further comprising transferring the data from the DRAM to the flash memory.

18. The method of claim 13, further comprising coordinating a timing of a data transfer between the flash memory and the DRAM with regard to a power level of the DRAM.

19. The method of claim 13, further comprising including a buffer within the DIMM to buffer the data transferred between the flash memory and the DRAM.

20. The method of claim 13, further comprising using an operating system to write to the ASIC a source address range to be copied and a target address range.
